(19) United States
(12) Patent Application Publication
(10) Pub. No.: US 2025/0019216 A1
(43) Pub. Date: Jan. 16, 2025

(54) CONVEYANCE DEVICE

(71) Applicant: DAIFUKU CO., LTD., Osaka (JP)

(72) Inventors: Akihiko TAKAHA, Shiga (JP); Satoshi TERAUCHI, Shiga (JP); Yoshiaki KITAGAWA, Shiga (JP)

(73) Assignee: DAIFUKU CO., LTD., Osaka (JP)

(21) Appl. No.: 18/746,220

(22) Filed: Jun. 18, 2024

(30) Foreign Application Priority Data
Jul. 14, 2023 (JP) 2023-116233

(51) Int. Cl. B66F 9/14; B66F 9/065

(52) U.S. Cl. CPC B66F 9/145; B66F 9/065

(57) ABSTRACT

A reduction in size is achieved of a conveyance device having the following three mechanisms: a traveling mechanism, a raising and lowering mechanism, and a turning mechanism. The conveyance device includes: a carriage on which a raising and lowering turning table is mounted; a traveling motor for causing the carriage to travel; a raising and lowering motor for raising and lowering the raising and lowering turning table; and a turning motor for turning the raising and lowering turning table, the traveling motor and the raising and lowering motor being provided such that respective rotation axes of the traveling motor and the raising and lowering motor extend horizontally and in the same direction, and the respective rotation axes are arranged in a row in an axis direction, the turning motor being provided such that a rotation axis of the turning motor is located in a position different from a position of a turning axis of the raising and lowering turning table, and the turning motor overlaps with neither the traveling motor nor the raising and lowering motor.

### CROSS REFERENCE TO RELATED APPLICATIONS

This application is based upon and claims the benefit of priority from Japanese Patent Application No. 2023-116233 filed on Jul. 14, 2023, the disclosure of which is incorporated herein in its entirety by reference.

### TECHNICAL FIELD

The present invention relates to a conveyance device.

### BACKGROUND ART

In a factory and the like, as a conveyance device for transferring an article to and from, for example, a station or a rack, a traveling carriage may be used which has (i) a raising and lowering mechanism for raising and lowering the article being held and (ii) a turning mechanism for turning the article being held. Patent Literature 1 discloses a conveyance robot which includes a traveling motor, a turning motor, and a raising and lowering motor.

### CITATION LIST

### Patent Literature

### [Patent Literature 1]

Japanese Patent Application Publication Tokukai No. 2017-109256

### SUMMARY OF INVENTION

### Technical Problem

Such conveyance devices are facing a demand for a reduction in size. It is an object of an aspect of the present invention to achieve a reduction in size of a conveyance device having the following three mechanisms: a traveling mechanism, a raising and lowering mechanism, and a turning mechanism.

### Solution to Problem

In order to attain the object, a conveyance device in accordance with an aspect of the present invention is a conveyance device, including: a raising and lowering turning table for raising, lowering, and turning a conveyance target that is placed on the raising and lowering turning table; a carriage on which the raising and lowering turning table is mounted; a traveling motor that provides a driving force for causing the carriage to travel; a raising and lowering motor that provides a driving force for moving the raising and lowering turning table in a raising and lowering direction with respect to the carriage; and a turning motor that provides a driving force for turning the raising and lowering turning table with respect to the carriage, the traveling motor and the raising and lowering motor being provided such that respective rotation axes of the traveling motor and the raising and lowering motor extend horizontally and in the same direction, and in a plan view, the respective rotation axes are arranged in a row in an axis direction, the turning motor being provided such that a rotation axis of the turning motor is located in a position different from a position of a turning axis of the raising and lowering turning table, and in a plan view, the turning motor overlaps with neither the traveling motor nor the raising and lowering motor.

### Advantageous Effects of Invention

According to an aspect of the present invention, it is possible to achieve a reduction in size of a conveyance device having the following three mechanisms: a traveling mechanism, a raising and lowering mechanism, and a turning mechanism.

### BRIEF DESCRIPTION OF DRAWINGS

FIG. 1 is a perspective view of a conveyance device in accordance with an embodiment of the present invention.

FIG. 2 is a perspective view of the conveyance device as viewed from another angle.

FIG. 3 is a perspective view of the conveyance device as viewed from still another angle.

FIG. 4 is a top view of the conveyance device.

FIG. 5 is a view illustrating a state in which a raising and lowering turning table is lowered in FIG. 1.

### DESCRIPTION OF EMBODIMENTS

### Embodiment

The following description will discuss details of an embodiment of the present invention. Note, however, that the following description discusses one example of a conveyance device 1 in accordance with the present invention, and the technical scope of the present invention is not limited to the examples in the drawings. The following description traveling direction D1 of the conveyance device 1 is an x-axis direction, a height direction of the conveyance device 1 is a z-axis direction, and a width direction of the conveyance device 1 perpendicular to the x-axis direction and the z-axis direction is a y-axis direction.

### [Outline of Conveyance Device]

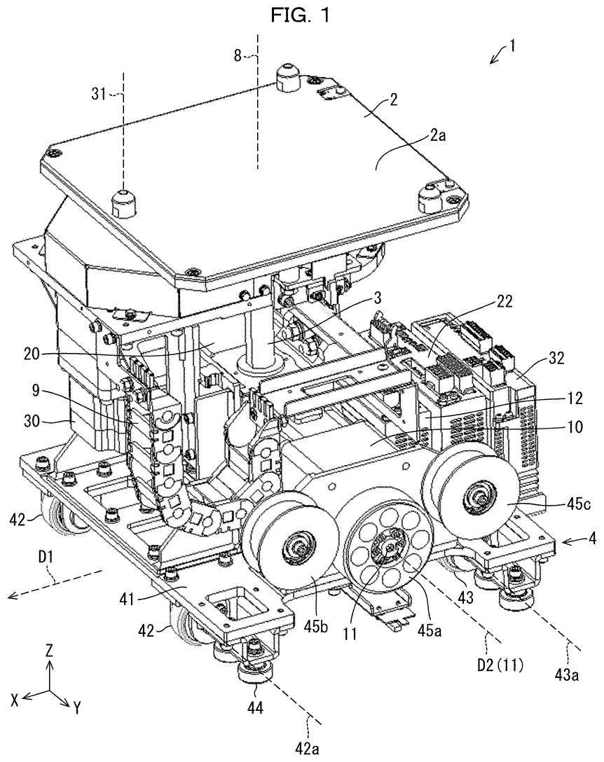

FIG. 1 is a perspective view of the conveyance device 1 in accordance with an embodiment of the present invention. FIG. 1 illustrates a state in which a raising and lowering turning table 2 is raised. As illustrated in FIG. 1, the conveyance device 1 includes a traveling motor 10, a raising and lowering motor 20, and a turning motor 30 in order to perform the following three functions: traveling; raising and lowering; and turning. The conveyance device 1 is designed to achieve a reduction in size by the following arrangements: (1) the traveling motor 10 and the raising and lowering motor 20 are provided such that respective rotation axes 11 and 21 of the traveling motor 10 and the raising and lowering motor 20 extend horizontally and in the same direction and, in a plan view, the respective rotation axes 11 and 21 are arranged in a row in an axis direction D2; and (2) the turning motor 30 is provided such that (i) a rotation axis 31 of the turning motor 30 is located in a position different from a position of a turning axis 8 of the raising and lowering turning table 2 and (ii) the turning motor 30 overlaps with neither the traveling motor 10 nor the raising and lowering motor 20 in a plan view.

### (Conveyance Device)

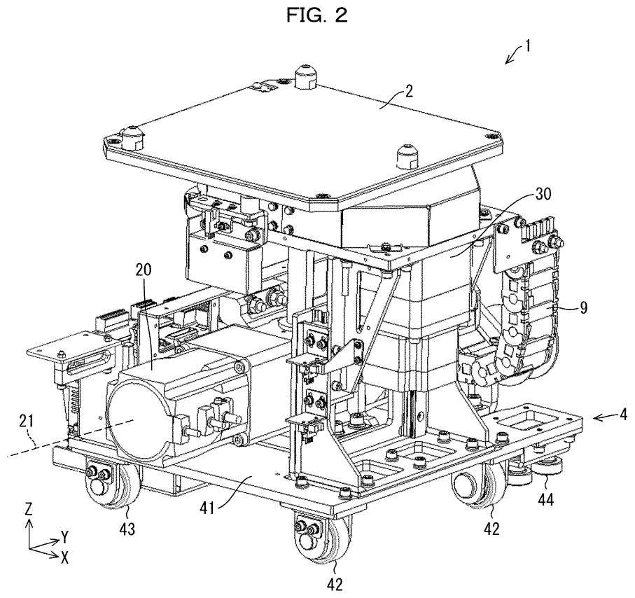

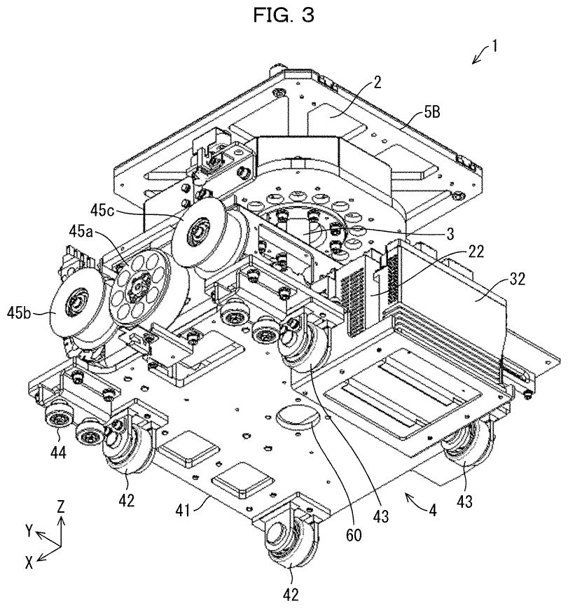

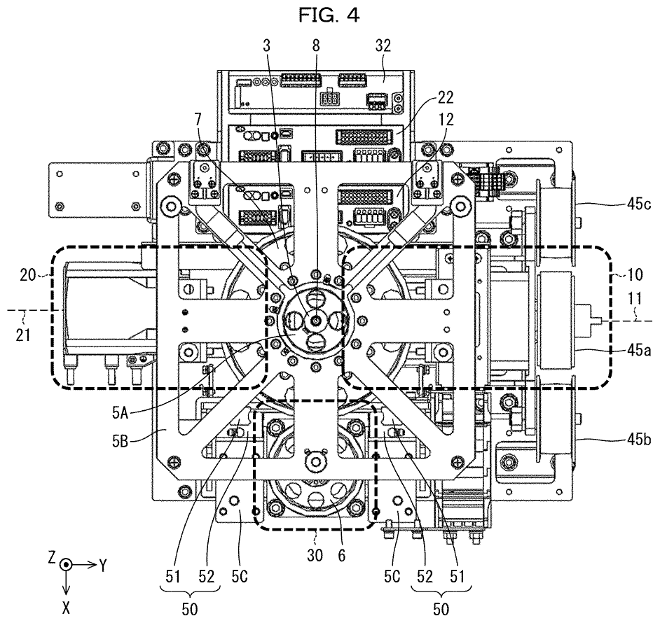

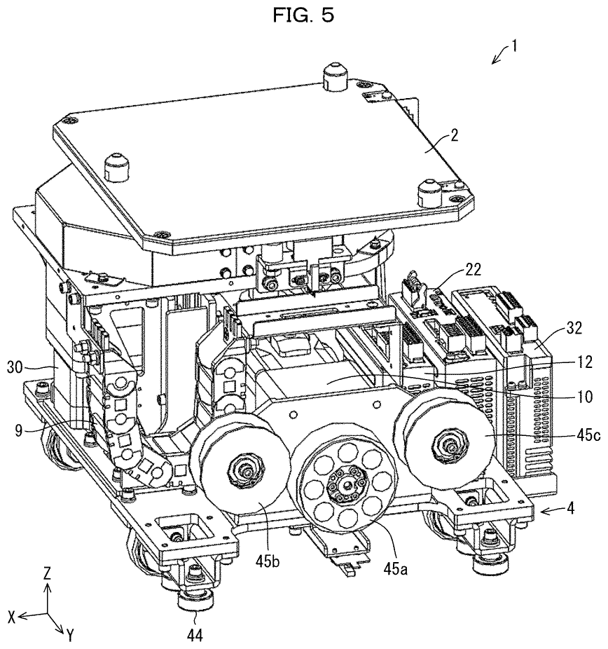

FIGS. 2 and 3 are each a perspective view of the conveyance device 1 as viewed from another angle different from an angle from which the conveyance device 1 is viewed in FIG. 1. FIG. 4 is a top view of the conveyance device 1, in which the raising and lowering turning table 2 is omitted from the conveyance device 1. FIG. 5 is a view illustrating a state in which the raising and lowering turning table 2 is lowered in FIG. 1. The following description will discuss the conveyance device 1 with reference to FIGS. 1 to 5.

The conveyance device 1 causes a carriage 4 to travel while a conveyance target is placed on the raising and lowering turning table 2, and raises, lowers, and turns the raising and lowering turning table 2. By this operation, the conveyance device 1, for example, moves the conveyance target into and out of a rack (not illustrated) which includes a storage section for storing the conveyance target. The conveyance target is used for storing a semiconductor, a liquid crystal panel, or the like, and is, for example, a front opening unified pod (FOUP).

As illustrated in FIGS. 1 and 2, the conveyance device 1 includes the raising and lowering turning table 2, the carriage 4, the traveling motor 10, a traveling drive circuit 12, the raising and lowering motor 20, a raising and lowering drive circuit 22, the turning motor 30, a turning drive circuit 32, and guide sections 50 (see FIG. 4). The raising and lowering turning table 2 has a conveyance target placed on an upper surface 2a thereof, and raises, lowers, and turns the conveyance target which is placed.

### (Carriage)

The carriage 4 has the raising and lowering turning table 2 mounted thereon. Each member of the conveyance device 1 is supported in a vertical direction by a carriage support section 41. The carriage 4 travels, by the traveling motor 10, in a moving path (not illustrated) formed in a groove shape along the traveling direction D1.

As illustrated in FIG. 3, the carriage 4 has a pair of front wheels 42 and a pair of rear wheels 43 on a lower surface of the carriage support section 41. The pair of front wheels 42 is provided on a front side of the carriage support section 41 in the traveling direction D1, and the pair of rear wheels 43 is provided on a rear side of the carriage support section 41 in the traveling direction D1. The front wheels 42 and the rear wheel 43 each have a rotation axis substantially parallel to the y-axis direction. The front wheels 42 and the rear wheels 43 are in contact with a traveling surface of the moving path and support the conveyance device 1 in the vertical direction. Note that the front wheels 42 and the rear wheels 43 are driven by neither the traveling motor 10 nor the traveling drive circuit 12. The front wheels 42 and the rear wheels 43 rotate by following the conveyance device 1 which travels using a toothed traveling belt (described later).

The carriage 4 has a pair of traveling guide rollers 44 on the lower surface of the carriage support section 41, on an outer side of a front wheel 42 and a rear wheel 43 that are on one side with respect to the traveling direction D1. An axis direction of the pair of traveling guide rollers 44 corresponds to the z-axis direction. In the moving path, a traveling guide rail (not illustrated) is laid along the traveling direction D1, and the pair of traveling guide rollers 44 is in contact with the traveling guide rail so as to sandwich the traveling guide rail from both sides.

### (Traveling Motor)

The traveling motor 10 provides a driving force for causing the carriage 4 to travel. The traveling motor 10 is driven by the traveling drive circuit 12. The traveling motor 10 is provided on the carriage support section 41 such that the rotation axis 11 extends horizontally and in a direction perpendicular to the traveling direction D1. That is, the traveling motor 10 is provided on the carriage support section 41 such that the rotation axis 11 extends parallel to the y-axis direction. The traveling motor 10 is provided on a side where the traveling guide rollers 44 are provided with respect to the traveling direction D1, such that an output shaft of the traveling motor 10 faces outward.

As illustrated in FIG. 1, a toothed driving pulley 45a is provided to the output shaft of the traveling motor 10. On a front side of the toothed driving pulley 45a in the traveling direction D1, a guide pulley 45b is provided such that a rotation axis of the guide pulley 45b extends substantially parallel to the toothed driving pulley 45a. On a rear side of the toothed driving pulley 45a in the traveling direction D1, a tension pulley 45c is provided such that a rotation axis of the tension pulley 45c extends substantially parallel to the toothed driving pulley 45a. Further, along the traveling direction D1 in the moving path, a toothed traveling belt (not illustrated) having both ends fixed is provided.

The traveling drive circuit 12 drives the traveling motor 10 so as to rotate the toothed driving pulley 45a to thereby draw the toothed traveling belt into the conveyance device 1 and feed the toothed traveling belt out of the conveyance device 1, with use of the guide pulley 45b and the tension pulley 45c. This causes the carriage 4 to travel along the moving path while being guided by the traveling guide rail with use of the traveling guide rollers 44.

### (Raising and Lowering Motor)

The raising and lowering motor 20 provides a driving force for moving the raising and lowering turning table 2 in a raising and lowering direction with respect to the carriage 4. The raising and lowering motor 20 is driven by the raising and lowering drive circuit 22.

As illustrated in FIGS. 1 and 2, the raising and lowering motor 20 has a raising and lowering shaft 3 which is in a cylindrical shape and extends in the vertical direction (z-axis direction). To an upper end of the raising and lowering shaft 3, the raising and lowering turning table 2 is provided via a first support section 5A (see FIG. 4) and a second support section 5B (see FIGS. 3 and 4).

The raising and lowering motor 20 is provided on the carriage support section 41 such that the rotation axis 21 extends horizontally and in a direction perpendicular to the traveling direction D1. That is, the raising and lowering motor 20 is provided on the carriage support section 41 such that the rotation axis 21 extends parallel to the y-axis direction. The raising and lowering motor 20 converts a rotation of the output shaft, which is provided so as to extend horizontally, into a vertically upward movement of the raising and lowering shaft 3 or into a vertically downward movement of the raising and lowering shaft 3. That is, the driving of the raising and lowering motor 20 causes the raising and lowering shaft 3 to move in an up-and-down direction. In accordance with this, the raising and lowering turning table 2 also moves in the up-and-down direction.

The raising and lowering motor 20 and the raising and lowering shaft 3 are realized by a rack and pinion configuration. Specifically, for example, a series of teeth that are uniform in shape are formed on the raising and lowering shaft 3 along a direction in which the raising and lowering shaft 3 extends, and a cylindrical gear that meshes with the teeth formed on the raising and lowering shaft 3 is attached to an output shaft of the raising and lowering motor 20. The raising and lowering motor 20 causes the cylindrical gear to rotate while meshing with the teeth of the raising and lowering shaft 3. The raising and lowering motor 20 thereby converts a rotational movement of the raising and lowering motor 20 into a raising and lowering movement of the raising and lowering shaft 3. The raising and lowering motor 20 can be, for example, a commercial product available by the name “lineared motor”.

As illustrated in FIG. 5, in a case where the raising and lowering turning table 2 is lowered, the raising and lowering shaft 3 protrudes from an opening 60 formed in a position of the carriage support section 41 which position corresponds to the raising and lowering shaft 3. This makes it possible to increase a distance by which the raising and lowering turning table 2 is raised and lowered, while a size of the conveyance device 1 in the vertical direction is reduced.

As illustrated in FIGS. 1 and 2, the traveling motor 10 and the raising and lowering motor 20 are provided on an upper surface of the carriage support section 41 such that the respective rotation axes 11 and 21 extend horizontally and in the same direction. Specifically, the traveling motor 10 and the raising and lowering motor 20 are provided such that the respective rotation axes 11 and 21 extend in the axis direction D2 (y-axis direction). This makes it possible to reduce a height of the conveyance device 1 and prevent a center of gravity of the conveyance device 1 from being located high, in comparison, for example, to a case in which the rotation axis 21 of the raising and lowering motor 20 is in the vertical direction.

Further, the traveling motor 10 and the raising and lowering motor 20 are provided such that, in a plan view, the respective rotation axes 11 and 21 of the traveling motor 10 and the raising and lowering motor 20 are arranged in a row in the axis direction D2. Specifically, the traveling motor 10 is provided such that, on the side where the traveling guide rollers 44 are provided with respect to the traveling direction D1, the rotation axis 11 of the traveling motor 10 extends substantially parallel to the y-axis direction. Further, the raising and lowering motor 20 is provided on a side opposite to the side where the traveling guide rollers 44 are provided with respect to the traveling direction D1, such that the raising and lowering motor 20 and the traveling motor 10 are arranged in a row such that the rotation axis 21 of the raising and lowering motor 20 substantially correspond to the axis direction D2 of the rotation axis 11. Note that the output shaft of the raising and lowering motor 20 faces a traveling motor 10 side.

Thus, the traveling motor 10 and the raising and lowering motor 20 are prevented from overlapping with each other in the vertical direction, and the size of the conveyance device 1 in the vertical direction can be reduced. The traveling motor 10 causes the entire carriage 4 to travel together with the conveyance target, and the raising and lowering motor 20 raises the raising and lowering turning table 2 and the like together with the conveyance target. As such, depending on the weight of the conveyance target and the like, there may be a case in which these motors are required to have a great driving force. In such a case, these motors are provided in sizes rather large for components used in the carriage 4, and each have a heavy weight as well. However, in the conveyance device 1, the traveling motor 10 and the raising and lowering motor 20 are provided in a manner described above, so that, even in a case where the traveling motor 10 and the raising and lowering motor 20 are large motors having great driving forces, the motors can be mounted in the conveyance device 1 in a compact manner. Further, since the raising and lowering shaft 3 can be located in a center part of the conveyance device 1, an improved stability is obtained when the raising and lowering turning table 2 is raised and lowered.

Further, the axis direction of the rotation axis 11 of the traveling motor 10 and the axis direction of the rotation axis 21 of the raising and lowering motor 20 correspond to the axis direction D2, and the axis direction D2 is orthogonal to the traveling direction D1 of the carriage 4. Thus, by adjusting positions of the traveling motor 10 and the raising and lowering motor 20 with respect to the traveling direction D1, it is easy to maintain a balance in a direction orthogonal to the traveling direction D1. This improves stability of traveling of the conveyance device 1.

The rotation axis 11 of the traveling motor 10 and the rotation axis 21 of the raising and lowering motor 20 are provided between a rotation axis 42a of each of the front wheels 42 and a rotation axis 43a of each of the rear wheels 43. Since the rotation axis 11 of the traveling motor 10 and the rotation axis 21 of the raising and lowering motor 20 are provided between the rotation axis 42a of each of the front wheels 42 and the rotation axis 43a of each of the rear wheels 43, the center of gravity of the carriage 4 is stable, and an improved stability is exhibited even during rapid acceleration and rapid deceleration in traveling.

As illustrated in FIGS. 1, 2, 4, and 5, the traveling motor 10 and the raising and lowering motor 20 are provided below the raising and lowering turning table 2 at positions where the traveling motor 10 and the raising and lowering motor 20 overlap with the raising and lowering turning table 2 in a plan view. The provision of the traveling motor 10 and the raising and lowering motor 20 below the raising and lowering turning table 2 makes it possible to save space. Further, between (i) the raising and lowering turning table 2 and (ii) the traveling motor 10 and the raising and lowering motor 20, gears (a drive gear 6 and a driven gear 7 described later) can be provided which gears transmit, to the turning axis 8 of the raising and lowering turning table 2, a driving force from the turning motor 30 for turning the raising and lowering turning table 2. This makes it possible to further reduce the size of the conveyance device 1.

### (Turning Motor)

The turning motor 30 provides a driving force for turning the raising and lowering turning table 2 with respect to the carriage 4. The turning motor 30 is driven by the turning drive circuit 32.

As illustrated in FIG. 4, the first support section 5A, which supports the raising and lowering turning table 2, is an annular member provided at the upper end of the raising and lowering shaft 3 so as to surround the raising and lowering shaft 3 while being centered around the raising and lowering shaft 3. The second support section 5B, which is a substantially quadrangular member, is provided so as to surround the first support section 5A while being centered around the first support section 5A.

On a lower surface of the second support section 5B, the driven gear 7 (described later) is provided, and on an upper surface of the second support section 5B, the raising and lowering turning table 2 is provided. The first support section 5A and the second support section 5B are connected to each other, rotatably relative to each other. As such, when the raising and lowering shaft 3 is raised, the first support section 5A, the second support section 5B, and the raising and lowering turning table 2 are raised together in an integral manner, whereas when the driven gear 7 is rotated, the first support section 5A is not rotated but only the second support section 5B and the raising and lowering turning table 2 are rotated.

Further, the drive gear 6 is provided to the output shaft of the turning motor 30, and the drive gear 6 and the driven gear 7 are provided such that respective outer circumferential surfaces of the drive gear 6 and the driven gear 7 mesh with each other. As such, when the turning motor 30 is driven, the driven gear 7 is rotated via the drive gear 6 to allow the raising and lowering turning table 2 to be turned.

The turning motor 30 is raised and lowered together with the drive gear 6, the driven gear 7, and the raising and lowering turning table 2. Specifically, both ends of the turning motor 30 in the y-axis direction are connected to a third support section 5C, and an upper surface of the third support section 5C is connected to the lower surface of the second support section 5B. As such, when the raising and lowering motor 20 is driven and the raising and lowering shaft 3 is raised, the third support section 5C is raised together with the second support section 5B, and the turning motor 30 is also raised, accordingly. This allows the raising and lowering turning table 2 to be turned irrespective of a height at which the raising and lowering turning table 2 is positioned.

A wire that connects the turning motor 30 with the turning drive circuit 32 provided on the carriage support section 41 is provided in a cable carrier 9 that moves following a movement of the turning motor 30. This allows the wire to be protected even when the turning motor 30 is raised and lowered together with the raising and lowering turning table 2.

As illustrated in FIGS. 1 and 4, the turning motor 30 is provided so as to overlap with neither the traveling motor 10 nor the raising and lowering motor 20 in a plan view. Specifically, in a plan view, the turning motor 30 is provided at a position spaced apart, in the traveling direction D1, from a line on which the traveling motor 10 and the raising and lowering motor 20 are arranged in a row. Further, the turning motor 30 is provided such that: the rotation axis 31 of the turning motor 30 is located in a position different from a position of the turning axis 8 of the raising and lowering turning table 2; and the rotation axis 31 of the turning motor 30 extends parallel to the turning axis 8 of the raising and lowering turning table 2.

Since the rotation axis 31 of the turning motor 30 is located at the position different from the position of the turning axis 8 of the raising and lowering turning table 2, it is possible to realize an arrangement in which, in a plan view, the turning motor 30 overlaps with neither the traveling motor 10 nor the raising and lowering motor 20. This makes it possible to reduce the size of the conveyance device 1 in the vertical direction. Further, since the turning motor 30 is provided such that the rotation axis 31 of the turning motor 30 extends parallel to the turning axis 8 of the raising and lowering turning table 2, a driving force of the turning motor 30 can be efficiently transmitted to the raising and lowering turning table 2.

### (Drive Circuit)

As illustrated in FIG. 1, on the upper surface of the carriage support section 41, the traveling drive circuit 12, the raising and lowering drive circuit 22, and the turning drive circuit 32 are arranged in a row in this order from the front side in the traveling direction D1 to the rear side in the traveling direction D1. This makes it possible to reduce a wiring distance in comparison to a case in which the respective drive circuits are other than the provided somewhere conveyance device 1.

Further, in a plan view, the traveling drive circuit 12, the raising and lowering drive circuit 22, and the turning drive circuit 32 are provided on a side opposite to a side on which the turning motor 30 is provided with respect to the line on which the traveling motor 10 and the raising and lowering motor 20 are arranged in a row. Specifically, with respect to the line on which the traveling motor 10 and the raising and lowering motor 20 are arranged in a row, the turning motor 30 is provided on a front side in the traveling direction D1, and the drive circuits are provided on a rear side in the traveling direction D1. As such, a good balance is achieved between one side (the front side in the traveling direction D1) and the opposite side (the rear side in the traveling direction D1) with respect to the axis direction D2 of the rotation axes 11 and 21 of the traveling motor 10 and the raising and lowering motor 20. This provides a stable traveling performance.

### (Guide Sections)

The guide sections 50 guide raising and lowering of the raising and lowering turning table 2. As illustrated in FIG. 4, the guide sections 50 are a pair, and in a plan view, one of the pair of guide sections 50, the turning motor 30, and the other of the pair of guide sections 50 are arranged side by side.

Since two guide sections 50 are provided instead of one guide section 50, it is possible to reduce a thickness of each guide section 50. This allows the turning motor 30 to be provided between the two guide sections, and thus makes it possible to reduce a distance between the turning axis 8 of the raising and lowering turning table 2 and the rotation axis 31 of the turning motor 30 (see FIG. 1). Further, since the guide sections 50 can be provided in the vicinity of the raising and lowering shaft 3 of the raising and lowering turning table 2, the raising and lowering shaft 3 can be assisted by the guide sections 50.

The guide sections 50 each have a guide rail 51 and a block 52. The guide rail 51 is provided in the vertical direction (z-axis direction), and the third support section 5C is provided to the block 52 engaged with the guide rail 51. As such, in a case where the third support section 5C is raised and lowered in the up-and-down direction, the third support section 5C is guided by the guide section 50. As described above, the upper surface of the third support section 5C is connected to the lower surface of the second support section 5B. As such, when the raising and lowering motor 20 is driven and the raising and lowering shaft 3 is raised, the third support section 5C is raised together with the second support section 5B, and the turning motor 30, which is guided by the guide section 50, is also raised together with the second support section 5B. As such, the raising and lowering turning table 2 is also guided by the guide section 50 via the third support section 5C and the second support section 5B.

Aspects of the present invention can also be expressed as follows:

A conveyance device (1) in accordance with Aspect 1 of the present invention is a conveyance device, including: a raising and lowering turning table (2) for raising, lowering, and turning a conveyance target that is placed on the raising and lowering turning table (2); a carriage (4) on which the raising and lowering turning table (2) is mounted; a traveling motor (10) that provides a driving force for causing the carriage (4) to travel; a raising and lowering motor (20) that provides a driving force for moving the raising and lowering turning table (2) in a raising and lowering direction with respect to the carriage (4); and a turning motor (30) that provides a driving force for turning the raising and lowering turning table (2) with respect to the carriage (4), the traveling motor (10) and the raising and lowering motor (20) being provided such that respective rotation axes of the traveling motor (10) and the raising and lowering motor (20) extend horizontally and in the same direction, and in a plan view, the respective rotation axes are arranged in a row in an axis direction (D2), the turning motor (30) being provided such that a rotation axis (31) of the turning motor (30) is located in a position different from a position of a turning axis (8) of the raising and lowering turning table (2), and in a plan view, the turning motor (30) overlaps with neither the traveling motor (10) nor the raising and lowering motor (20).

According to the above configuration, the rotation axis of the traveling motor and the rotation axis of the raising and motor extend lowering horizontally and in the same direction, and the motors are arranged in a row in an axis direction of each of the motors. This prevents the traveling motor and the raising and lowering motor from overlapping with each other in the vertical direction, and makes it possible to achieve a reduction in size in the vertical direction. As such, even in a case where the traveling motor and the raising and lowering motor are large motors having great driving forces, the motors can be mounted in the conveyance device in a compact manner. Further, it is possible to achieve a reduction in height and prevent a center of gravity of the conveyance device from being located high, in comparison, for example, to a case in which the rotation axis of the raising and lowering motor extends in the vertical direction.

Further, the turning motor is provided at a position at which (i) the rotation axis of the turning motor is located at the position different from the position of the turning axis of the raising and lowering turning table and (ii) in a plan view, the turning motor overlaps with neither the traveling motor nor the raising and lowering motor. Thus, the turning motor overlaps with neither the traveling motor nor the raising and lowering motor in the vertical direction, and a reduction in size in the vertical direction is therefore achieved.

This enables a reduction in size of a conveyance device having the following three mechanisms: a traveling mechanism, a raising and lowering mechanism, and a turning mechanism.

In Aspect 2 of the present invention, the conveyance device (1) described in Aspect 1 can be configured such that the conveyance device (1) further includes: a traveling drive circuit (12) that drives the traveling motor (10); a raising and lowering drive circuit (22) that drives the raising and lowering motor (20); and a turning drive circuit (32) that drives the turning motor (30), wherein in a plan view, the traveling drive circuit (12), the raising and lowering drive circuit (22), and the turning drive circuit (32) are provided on a side opposite to a side on which the turning motor (30) is provided with respect to a line on which the traveling motor (10) and the raising and lowering motor (20) are arranged in a row.

According to the above configuration, a good balance is achieved between one side and the opposite side with respect to the axis direction of the rotation axes 11 and 21 of the traveling motor and the raising and lowering motor. This provides a stable traveling performance.

In Aspect 3 of the present invention, the conveyance device (1) described in Aspect 1 or 2 is configured such that the conveyance device (1) further includes a pair of guide sections (50) that guides raising and lowering of the raising and lowering turning table (2), wherein in a plan view, one of the pair of guide sections (50), the turning motor (30), and the other of the pair of guide sections (50) are arranged side by side.

According to the above configuration, two guide sections are provided instead of one guide section. This makes it possible to reduce a thickness of each guide section. This allows the turning motor to be provided between the two guide sections, and thus makes it possible to reduce a distance between the turning axis of the raising and lowering turning table and the rotation axis of the turning motor. Further, since the guide sections can be provided in the vicinity of the raising and lowering shaft of the raising and lowering turning table, the raising and lowering shaft can be assisted by the guide sections.

In Aspect 4 of the present invention, the conveyance device (1) described in any one of Aspects 1 to 3 can be configured such that the turning motor (30) is provided such that the rotation axis of the turning motor (30) extends parallel to the turning axis (8) of the raising and lowering turning table (2).

According to the above configuration, since the turning motor is provided such that the rotation axis of the turning motor extends parallel to the turning axis of the raising and lowering turning table, a driving force of the turning motor can be efficiently transmitted to the raising and lowering turning table.

In Aspect 5 of the present invention, the conveyance device (1) described in any one of Aspects 1 to 4 can be configured such that: an axis direction (D2) of the rotation axis (11) of the traveling motor (10) and an axis direction (D2) of the rotation axis (21) of the raising and lowering motor (20) are orthogonal to a traveling direction (D1) of the carriage (4); and in a plan view, the turning motor (30) is provided at a position spaced apart, in the traveling direction (D1), from a line on which the traveling motor (10) and the raising and lowering motor (20) are arranged in a row.

According to the above configuration, the axis direction of the rotation axis of the traveling motor and the axis direction of the rotation axis of the raising and lowering motor are orthogonal to the traveling direction of the carriage. Thus, by adjusting positions of the traveling motor and the raising and lowering motor with respect to the traveling direction, it is easy to maintain a balance in a direction orthogonal to the traveling direction. This improves stability of traveling of the conveyance device.

Further, since the turning motor is provided at a position spaced apart, in the traveling direction, from the line on which the traveling motor and the raising and lowering motor are arranged in a row, it is possible to provide the turning motor such that the turning motor overlaps with neither the traveling motor nor the raising and lowering motor in the vertical direction. This enables a reduction in size in the vertical direction.

In Aspect 6 of the present invention, the conveyance device (1) described in any one of Aspects 1 to 5 can be configured such that: the carriage (4) has a pair of front wheels (42) and a pair of rear wheels (43); and the rotation axis (11) of the traveling motor (10) and the rotation axis (21) of the raising and lowering motor (20) are provided between a rotation axis (42a) of each of the front wheels (42) and a rotation axis (43a) of each of the rear wheels (43).

According to the above configuration, since the traveling motor and the raising and lowering motor are provided between the rotation axis of each of the front wheels and the rotation axis of each of the rear wheels, the center of gravity of the carriage is stable, and an improved stability in traveling is exhibited.

The present invention is not limited to the embodiments, but can be altered by a skilled person in the art within the scope of the claims. The present invention also encompasses, in its technical scope, any embodiment derived by combining technical means disclosed in differing embodiments. Further, it is possible to form a new technical feature by combining the technical means disclosed in the respective embodiments.

### REFERENCE SIGNS LIST

1: Conveyance device
2: Raising and lowering turning table
4: Carriage
8: Turning axis
10: Traveling motor
11: Rotation axis of traveling motor
12: Traveling drive circuit
20: Raising and lowering motor
21: Rotation axis of raising and lowering motor
22: Raising and lowering drive circuit
30: Turning motor
31: Rotation axis of turning motor
32: Turning drive circuit
42: Front wheel
42a: Rotation axis of front wheel
43: Rear wheel
43a: Rotation axis of rear wheel
50: guide section

1. A conveyance device, comprising:
a raising and lowering turning table for raising, lowering, and turning a conveyance target that is placed on the raising and lowering turning table;
a carriage on which the raising and lowering turning table is mounted;
a traveling motor that provides a driving force for causing the carriage to travel;
a raising and lowering motor that provides a driving force for moving the raising and lowering turning table in a raising and lowering direction with respect to the carriage; and
a turning motor that provides a driving force for turning the raising and lowering turning table with respect to the carriage,
the traveling motor and the raising and lowering motor being provided such that
respective rotation axes of the traveling motor and the raising and lowering motor extend horizontally and in the same direction, and
in a plan view, the respective rotation axes are arranged in a row in an axis direction,
the turning motor being provided such that
a rotation axis of the turning motor is located in a position different from a position of a turning axis of the raising and lowering turning table, and
in a plan view, the turning motor overlaps with neither the traveling motor nor the raising and lowering motor.

2. The conveyance device as set forth in claim 1, further comprising:
a traveling drive circuit that drives the traveling motor;
a raising and lowering drive circuit that drives the raising and lowering motor; and
a turning drive circuit that drives the turning motor,
wherein in a plan view, the traveling drive circuit, the raising and lowering drive circuit, and the turning drive circuit are provided on a side opposite to a side on which the turning motor is provided with respect to a line on which the traveling motor and the raising and lowering motor are arranged in a row.

3. The conveyance device as set forth in claim 1, further comprising a pair of guide sections that guides raising and lowering of the raising and lowering turning table,
wherein in a plan view, one of the pair of guide sections, the turning motor, and the other of the pair of guide sections are arranged side by side.

4. The conveyance device as set forth in claim 1, wherein the turning motor is provided such that the rotation axis of the turning motor extends parallel to the turning axis of the raising and lowering turning table.

5. The conveyance device as set forth in claim 1, wherein:
an axis direction of the rotation axis of the traveling motor and an axis direction of the rotation axis of the raising and lowering motor are orthogonal to a traveling direction of the carriage; and
in a plan view, the turning motor is provided at a position spaced apart, in the traveling direction, from a line on which the traveling motor and the raising and lowering motor are arranged in a row.

6. The conveyance device as set forth in claim 5, wherein:
the carriage has a pair of front wheels and a pair of rear wheels; and
the rotation axis of the traveling motor and the rotation axis of the raising and lowering motor are provided between a rotation axis of each of the front wheels and a rotation axis of each of the rear wheels.
